(19) United States
(12) Patent Application Publication
(10) Pub. No.: US 2015/0077961 A1
(43) Pub. Date: Mar. 19, 2015

(54) CONTROLLED IMPEDANCE PCB ENCAPSULATION

(71) Applicants: Jack Thiesen, Plymouth, MI (US); Karl Brakora, Dexter, MI (US)

(72) Inventors: Jack Thiesen, Plymouth, MI (US); Karl Brakora, Dexter, MI (US)

(73) Assignee: BT Engineering, Dexter, MI (US)

(21) Appl. No.: 13/751,317

(22) Filed: Jan. 28, 2013

(51) Int. Cl. H05K 9/00; H05K 1/18

(52) U.S. Cl. CPC H05K 9/00; H05K 1/181
USPC 361/765

(57) ABSTRACT

The present invention discloses methods and devices for encapsulating PCBs, assemblies of PCBs, and their electronic components. The encapsulation methods disclosed can be used to produce electromagnetic shields whose impedance is controlled.

This application claims the benefit of U.S. Provisional Patent Application No. 61/591,942, filed Jan. 29, 2012.

### BACKGROUND OF THE INVENTION

The present invention relates to methods for encapsulating electronic assemblies. As an example, the invention teaches methods for completely encapsulating a printed circuit board and all of its components within a nonconductive coating whose layer thickness is precisely controlled and subsequently encapsulating the previously encapsulated assembly within a conformal conductive coating.

Coating and shielding electronic components and assemblies serve many purposes. One is to reduce the effects of water and corrosive agents on the electronic components. Another is to provide electromagnetic interference shielding, known as EMI shielding, from external electromagnetic radiation sources. Yet another is to eliminate noise between components. Various patents teach methods to shield circuit boards U.S. Pat. No. 5,696,196 teaches of an aqueous based polymer dispersion with a metal particle suspension that can be used to coat plastic surfaces to create EMI shields.

The encapsulation of printed circuit boards known as PCBs for EMI shielding purposes is well known. U.S. Pat. No. 6,717,485 teaches of a method using liquid polymer coatings to completely encapsulate a PCB with first a conformal non-conducting layer coating and then a conductive coating. Similarly U.S. patent application Ser. No. 12/777,775 teaches a similar invention with the addition of using decals or shrink wrap for the conformal non-conducting layer and physical vapor deposition of metal layers.

None of the previous teachings describe deposition methods that can produce controlled impedance conformal coatings. Controlled impedance is important if coatings are to be used in high speed circuitry, radio frequency systems, which require precise signal timing and impedance matching, and for the production of durable surfaces. The previous teachings and prior art provide for conformal conducting layer layers of insufficient quality so that complete EMI shielding is impractical. Physical vapor deposition of conformal conducting layers is not conformal. The layers vary in thickness and deposition cannot occur beneath surfaces. While the use of loaded or intrinsically conducting polymers produce coatings which must either be impractically thick to stop EMI due to excessive skin depths. Improved encapsulation can allow for the complete suppression of EMI effects and improved performance.

A significant deficiency of prior teaching which do not indicate gas-phase conformal encapsulation, but rather coating techniques from liquid phase is the fact that such deposition techniques often leave behind large occlusions in the surface. For a 200 MHz cutoff and 80 dB of isolation, the largest gap in the shield would be 75 μm (0.003″), which is a small opening, but easily achieved with conformal gas-phase deposition. For a 2 GHz impinging frequency, the gap size is impractically small if vapor phase deposition techniques are not used. For this reason gas-phase mediated deposition techniques are required to provide complete conformal coating and therefore complete isolation.

Another deficiency of previous teachings is also due to lack of conformality of the coating techniques disclosed as means to produce EMI shields. In techniques involving dipping, painting, or spraying small pockets are formed that leave high stress points that cause failures when the coated samples are heated and cooled due to typical use condition. Sputtering or other means of physical vapor deposition impose difficult to control stresses as the coating layer grows. These stresses and non-uniformities due to shadowing of the surface by three dimensional parts also cause delamination failures when coated samples undergo heating and cooling.

Complete encapsulation of electronic assemblies by growing coating layers from a gas-phase mediated process eliminates the deficiencies of previous conformal coating techniques. Encapsulation produces layers with atomic scale thickness control and uniformity, it produces layers that improve adhesion and are stress neutral so that samples can undergo heating and cooling cycles without delamination of the coating.

Encapsulation provides these and many other benefits as will be disclosed in this teaching.

### SUMMARY OF THE INVENTION

The present invention addresses deficiencies in current encapsulation and shielding devices by providing a design for controlled impedance conformal EMI shields. This teaching also describes methods for fabricating these EMI shields whose manufacturing complexity is greatly reduced, and which provide a greater degree of EMI and chemical protection.

The present invention includes devices that have conformal non-conducting layer conformal coatings deposited from the gas phase and whose thickness is uniform over the entire board and whose thickness may be precisely controlled. These devices include openings formed in the gas phase deposited conformal non-conducting layer coatings over ground pads to allow for the shunting of EMI signals to ground. These devices also include a conformal contiguous conducting coating that will completely encapsulate the conformal non-conducting layer coating while at the same time making electrical contact to ground points with no additional connections required.

The major advantages of this teaching, which will become apparent as the invention is described, include complete EMI shielding, low cost batch formation of the coatings, lower weight of the coating, reduced manufacturing complexity, and increased electrical circuit densities due to improved isolation and noise suppression.

### BRIEF DESCRIPTION OF THE DRAWINGS

The present invention will be better understood by reference to the following discussion and when read in conjunction with the appropriate drawings in which like reference characters refer to like parts throughout the views, in which:

FIG. 1 depicts an encapsulated printed circuit board. 120 is a conformal non-conducting encapsulation layer formed over the entire printed circuit board, 100, and deposited from the gas-phase. 125 is a conformal conducting layer also formed from the gas-phase completely and encapsulating layer 120 and printed circuit board 100. 140 is a representation of a QFN packaged integrated circuit which is attached to the printed circuit board substrate 100. 144 is a representation of an integrated circuit packaged in a BGA package also attached on PCB 100. 144 is a representation of an integrated circuit packaged in SOT also attached to PCB 100. Picket vias, 102, contained within PCB 100 which are used to suppress unwanted signals carried through PCB 100 and between integrated circuits 144, 140, and 148 or any other integrated circuits or types of integrated circuits that may be present. An electrical connection, 115, between picket vias, 102, and the conductive coating, 125, formed by forming the conformal conducting layer layers over the surfaces which includes openings allowing for electrical contact between 125 and 102. Thermal vias 101 which principally serve to move heat from an IC to a ground plane but which may also serve as ground vias and may also have electrical connection to conducting layer 125. The conducting layer 125 is connected to electrical points on vias 102 and thermally contacting vias 101 through openings 121, 122, and 123 formed in the non-conducting layer 120.

FIG. 2—Is similar to FIG. 1 with the exception that there has been an additional conformal non-conducting layer, 219, disposed over the first conformal conducting layer, 225. There has also been a second conformal conducting layer, 226, disposed over the second conformal non-conducting layer 219. The second conformal conducting layer has a magnetic permeability for improved shielding effectiveness. Conducting layer 226 may optionally be electrically connected to the grounding 215 by forming an opening in layer 219.

FIG. 3 is a representation of an assembly of encapsulated printed circuit boards. The plurality of printed circuit boards 320 are attached to backplane 350 by means of connectors 330. According to the present invention the entire assembly maybe coated with an encapsulating non-conductive coating and a subsequent encapsulating conductive coating for shielding. This encapsulation may occur in one step without disassembly of the constituent components.

FIG. 4 is a stepwise depiction of a preferred method for the formation of an opening such as 121, 122, and 123 in dielectric layer 120 used to form electrical or thermal contacts such as 115 between vias 102 and layer 125 as depicted in FIG. 1. In this method for forming openings, printed circuit board 400 with via 402 has a masking material 403 placed over the electrical surface of via 402; Step 1. An encapsulating non-conductive coating 404 is disposed entirely over the mask material 403 and printed circuit board 400; Step 2. An opening 410 is formed in the encapsulating non-conductive coating 404 exposing the mask material 403 and subsequently the masking material is selectively removed exposing printed circuit board 400; Step 3. A first encapsulating conductive coating 425 is formed over the non-conductive coating 404 and around the opening and the cavity formed by the absent making material; Step 4. A second optional conductive coating 426 is formed over first conductive coating 425 possibly filling the hole and cavity with conformal conducting layer 426; Step 5.

FIG. 5 illustrates one means for making a single point contact for the conduction of voltage between conformal conducting layer, 525, and a chassis ground of an instrument enclosure. Shown here is a screw, 510, that mechanically clamps the upper electrical contact, 531, and the threaded nut that forms the lower electrical contact, 530. Both 530 and 531 form electrical contact to the outer conformal conducting layer, 525, that has been formed over non-conducting layer, 520, both of which completely encapsulate printed circuit board, 500. This provides a means to shunt electrical potentials arising on conformal conducting layer 525 to ground via the single point electrical connection, 501. It should be understood that although a mechanical connection using a screw is disclosed as the means to electrically connect upper and lower shield contacts any convenient means may be used such as, conducting epoxies, solder, or rivets as examples.

FIGS. 6 and 7 depict a means of forming conducting contacts between two halves of a shrouded electrical connector for the purpose of providing encapsulating shielding. FIG. 6 is a stepwise depiction of a means for forming electrical contacts on one side of the connector. A tight fitting mask, 601, is used to protect the metal surfaces of the contact pins while conformal non-conducting layer, 620, is disposed over the connector and the printed circuit board, 600, to which it is attached; Step 1. At the completion of Step 1 the tight fitting mask material, 601, may be removed and replaced with a loose fitting mask, 602 or the original mask may be left in place. A conformal conducting layer, 626, is disposed making a conducting seal along the mating surfaces of the shroud; Step 2.

FIG. 7 illustrates a means for connector shielding using the techniques depicted in FIG. 6. In 7A the upper shroud, 750, has been masked during the encapsulating deposition of non-conducting layer 720 and conducting layer 725 over the connector half attached to printed circuit board 700. 7B illustrates the result of formation of an encapsulating non-conducting layer 721 and conducting layer 726 over the shrouded connector half, 751, attached to printed circuit board 701. The layers are formed over 751 using a method similar to that in FIG. 6. After deposition of the layer 726 on 751 the masking material, 620/621, is removed with one result illustrated in FIG. 7B. The removal of the mask leaves conducting layer 726 on top surface of shroud 751. When 750 and 751 are mated the two electrically conducting surfaces, 726 and 725, make electrical contact and provide effective shielding for the connector.

### DETAILED DESCRIPTION OF THE INVENTION

The invention is described here in terms of preferred embodiments, structures, and method steps, however, it will be understood that substitutions and equivalents as will be apparent to those of ordinary skill in the art may be used without departing from the scope of the invention as defined by the appended claims.

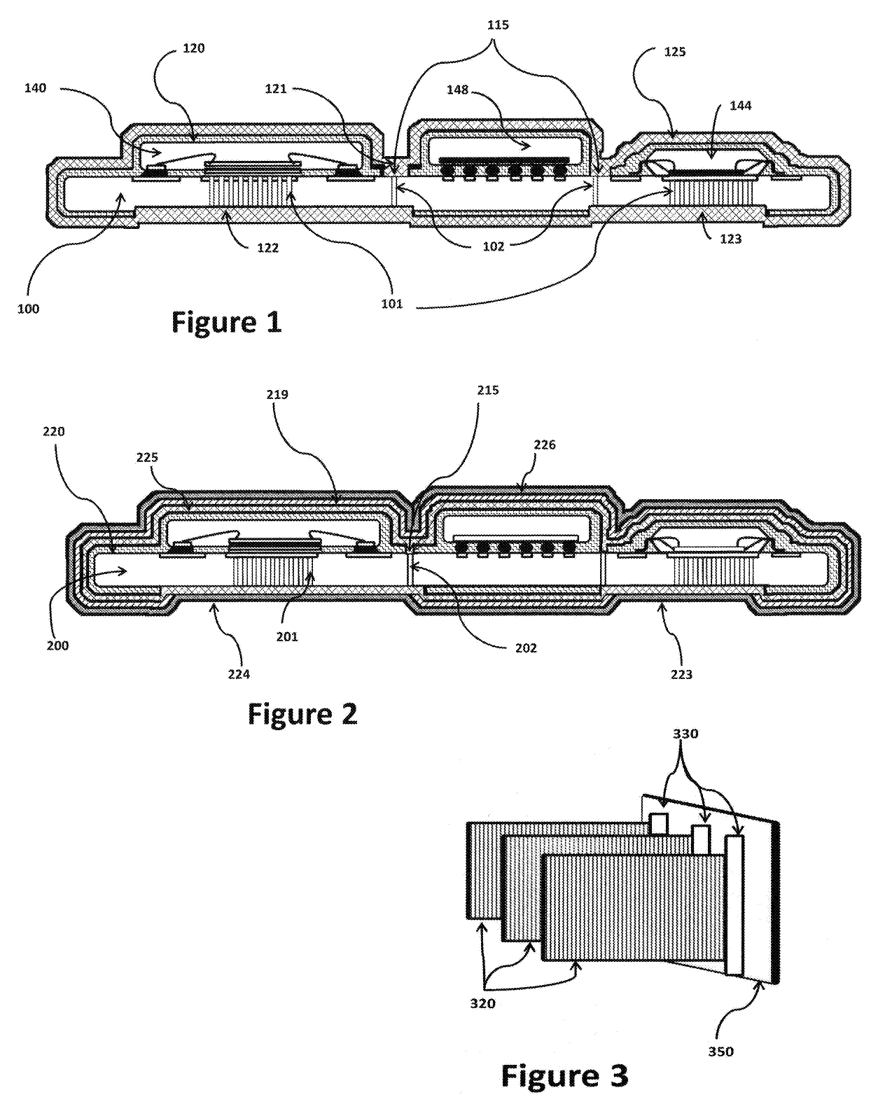

According to the invention, a device comprised of a printed circuit board (100 in FIG. 1) populated with integrated circuits, has a non-conductive coating layer, 120, formed from a gas-phase deposition process which conformally encapsulates printed circuit board, 100, and all of the integrated circuits in their entirety. To be a gas-phase derived product, the coating process must occur under reduced pressure so that the molecules forming the coating have sufficient diffusion lengths so as to coat beneath surfaces.

This is typically accomplished using a vacuum. Subsequently, a gas-phase phase derived conductive coating, 125, encapsulates the entirety of the PCB, 100, and the integrated circuits on the PCB. Openings can be formed in layer 120 prior to deposition of layer 125, to allow conducting layer 125 to make contact with conducting vias as exemplified by 102. Methods for forming such opening include an optional masking to prevent the nonconductive gas-phase derived coating or the mechanical formation of holes such as in FIG. 6. During the formation of layer 120 and 125 and all subsequent layers, masking is used to prevent the nonconductive gas phase derived coating and the conductive coating from forming on connectors or other structures attached to PCB, 100 that are not to be encapsulated.

The device in FIG. 1 is realized by placing a circuit board, or many circuit boards, typified by 100 into a reaction vessel. In one such reactor, a non-conducting polymer layer of a precisely controlled thickness is formed over every surface within the reactor including PCB 100 and all of the circuits disposed on its surface. An example of one such suitable conformal material process is vapor polymerized Parylene. Another example is gas-phase derived Al2O3 using a reactor that performs atomic layer deposition, known as ALD. The use of a gas-phase deposition process such as gas-phase polymerization of parylene or gas-phase formation of Al2O3 by ALD allows every surface to be completely coated.

Alternatives to Parylene are any number of polymers formed from monomers such as ethylene, propylene, styrene, benzene, toluene, xylene, chlorobenzene, 1,2,4-trichlorobenzene, ferrocene, ethlybenzene, or any other monomer known, by those skilled in the art, to produce a thickness controlled polymer film using gas phase deposition techniques. All of the preferred reaction techniques can be performed at low temperatures, <120C which is compatible with most printed circuit board and electronic component survival parameters. Complete encapsulation in vacuum conditions precludes the formation of air bubbles and other gaps which make the design of impedance controlled layers impossible. Precise control of the thickness of the non-conducting layer 120 is critical to controlling the impedance of the electrical wires already formed on circuit board 100. Thickness may be monitored and the process controlled using a quartz mass balance situated in the reaction vessel, by controlling deposition rate and time, or by any similar means known to those skilled in the art. The fact that multiple circuit boards may be simultaneously coated reduces the cost of the layer as the single run cost of operating the reactor is divided by the number of boards being coated. Although only two gas-phase deposition processes have been cited many such processes are known for the deposition of conformal non-conducting layers and any suitable similar process may be used to form the device.

Subsequent to the formation of the non-conductive layer an opening or openings, such as 115 in FIG. 1, can be formed in the as-deposited non-conducting layer 120 using any suitable technique such as abrasion, controlled depth drilling, laser etching, laser ablation, or any means deemed suitable that does not compromise the encapsulation of the non-conductive layer, 120, around the PCB and it components. Openings may also be formed in advantageous locations using physical masking. These opening can positioned advantageously over vias, 102, and/or grounding pads so that during deposition of conducting layer, 125, it can make electrical connection with features on the PCB. This can be used to provide ground isolation between integrated circuits and traces disposed on the surface of PCB 100. It should be noted that although PCB 100 shows only 3 types of IC packaging any type of IC packaging may be encapsulated as well as signal lines, passive components such as capacitors, inductors, and circuit board devices such as signal power splitters, signal lines, signal combiners. Encapsulation can also cover discrete components such as diodes and transistors, capacitor and inductors and all other components. The via pickets 102 on PCB 100 and the openings disposed over these pickets can be placed around the components and integrated circuits at intervals determined the most advantageous to suppress unwanted signals generated from a particular IC or component from reaching another IC or component located on the same circuit board. Or they can be spaced to suppress unwanted electromagnetic interference from affecting components on PCB 100.

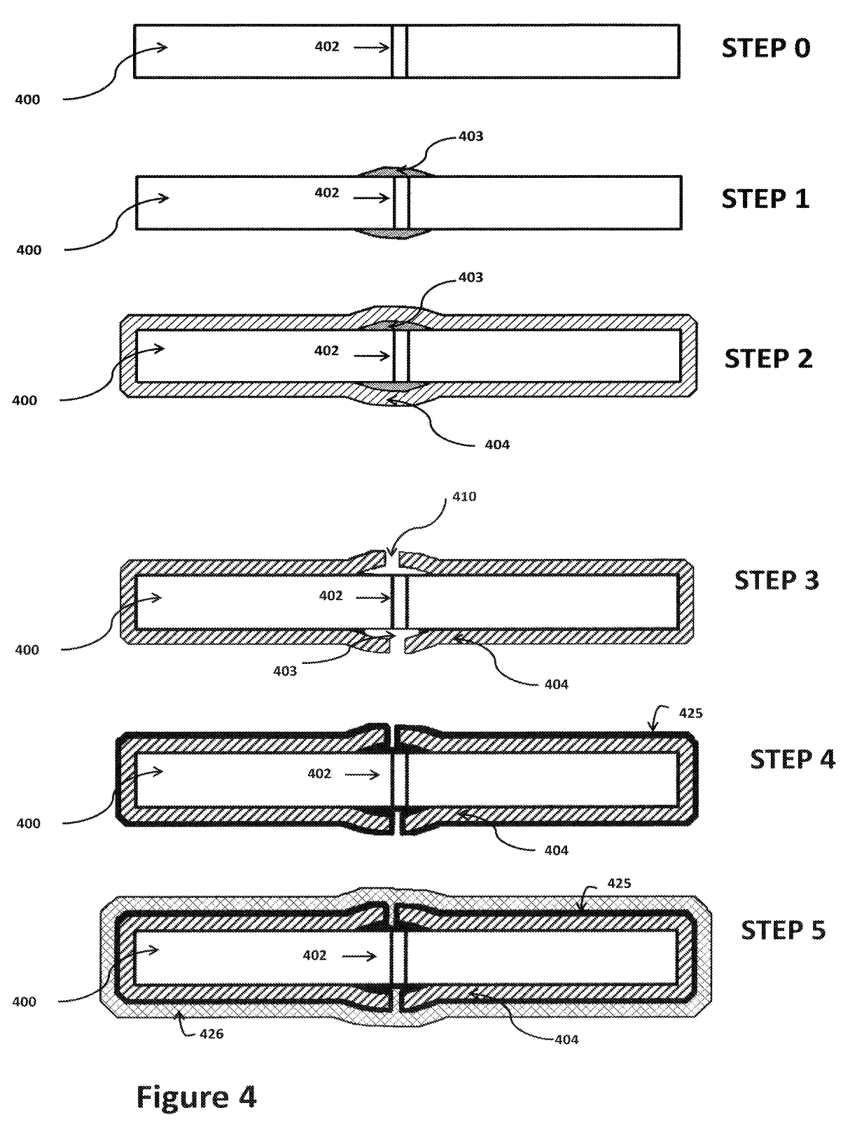

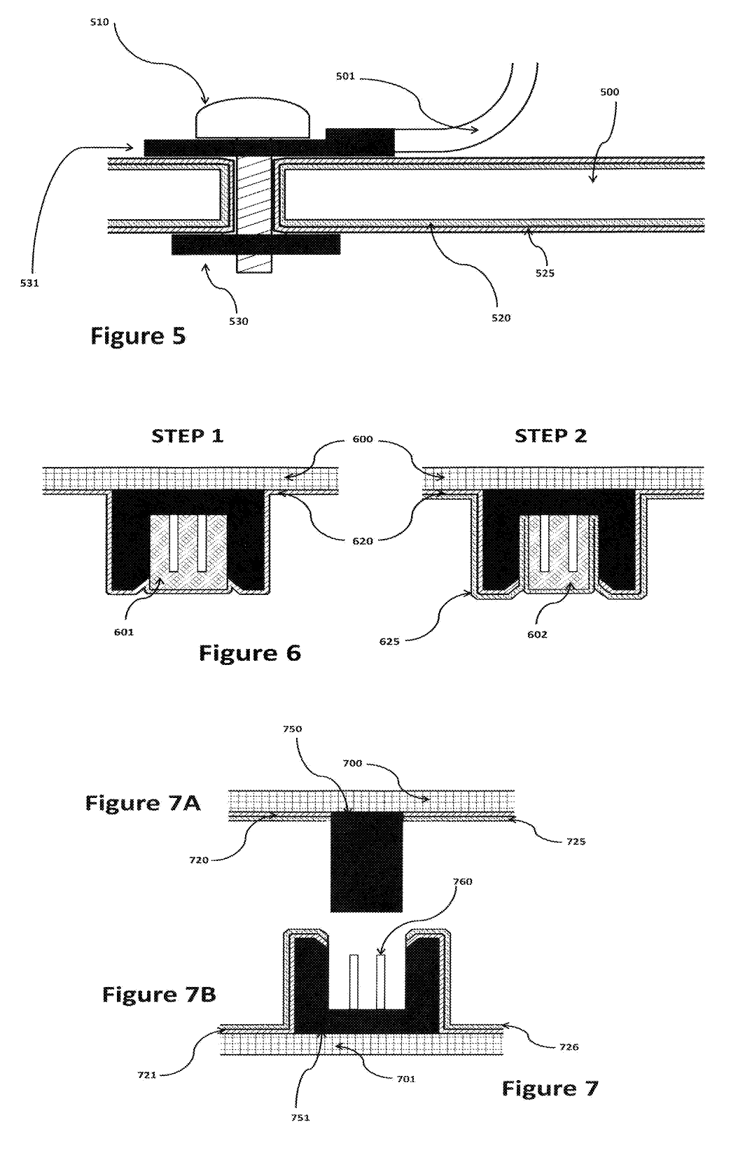

One method for the formation of openings is shown in FIG. 4 following steps 1 through 5. In this method for forming openings, circuit boards 400 with vias 402 have a masking material 403 placed over the electrical surface of via 402; Step 1. Suitable masking materials are polymer coatings that can be disposed as single drops with sufficient viscosity to form correctly dimensioned coverings and which can be dissolved in simple solvents that do not affect the PCB or the non-conductive coating. Examples of suitable polymers are partially cured high molecular weight polymethylmethacrylate, or SU-8 photoresist all of which can be soluble in simple organic solvents. Other suitable polymer solvent combinations are of course possible and within the spirit of this teaching. An encapsulating non-conductive coating 404 is formed over the mask material 403 and PCB 400; Step 2. A hole 410 is formed in through the encapsulating non-conductive coating 404 and the mask material 403 is dissolved by a allowing a solvent to enter through the hole; Step 3. This hole may be formed using any convenient method such as drilling, laser ablation, abrasion, or any suitable means. Mask material 303 cab be dissolved using any suitable solvent that does not affect non-conducting layer 404. An encapsulating conductive coating 425 is formed over non-conductive coating 404 and over the surfaces of the cavity left by the dissolution of the masking material. A second optional conductive coating 426 is formed over first conductive coating 425.

After formation of the openings in non-conductive layer 120, a conductive layer, exemplified by 125 in FIG. 1, is formed. The preferred embodiment forms the conductive layer using a gas-phase process such as atomic layer deposition, ALD, which can form any number of encapsulating conformal conducting layer layers such as iron, silver, tungsten, copper, cobalt, titanium, molybdenum, tantalum, platinum, palladium, ruthenium, aluminum, and conducting ceramics or oxides such as zinc-oxide. Many these layers can be formed at temperatures compatible with PCB and component survival parameters. Further, these layers may be formed of varying thicknesses. The preferred embodiment of this invention uses rapid cycle ALD processes which can form layers in short times. The formation of these conformal conducting layers from the gas-phase over the entirety of the PCB and the non-conducting layer, 120, and the openings in the non-conducting layer ensure that there will be electrical connection, 115, between the conducting layer 125 and picket vias 102. This is as described in the preceding text.

The preferred embodiment of this invention has a conducting layer, 125, whose thickness is at least two skin-depths at the lowest electromagnetic frequency that it is desired to shield. However, for low-frequency shielding this is not practical and the initial conducting layer 125 may have its thickness augmented with a subsequent liquid phase deposition process such as electrochemical plating of another conformal conducting layer that is much thicker. Such plating processes, electrolytic or electroless, can form metals such as Cu, Ni, Fe, and many others as well as alloys. The use of these materials allows for the tailoring of shielding properties to the application. An advantage of this teaching is that the initial conducting layer, 125, acts as an encapsulating seed layer and protects non-conducting layer 120 from water uptake from an aqueous bath and provides protecting for the PCB and its components from a chemically aggressive electroless or electrolytic solution. Preventing layer 120 from taking water is important to the integrity of the metal coating and the survival of the encapsulated electronics. Another advantage of this teaching is that the conformal layer 125 completely encapsulates the electronic assembly and thus the plating layer can also completely encapsulate the electronic assembly.

Prior to deposition of the conductive layer 125 an optional activation treatment may occur on the surface of non-conducting layer 120. Such a process can be realized by exposure to gap-phase plasma of oxygen, sulfurhexafluoride, nitrogen, helium, argon or any suitable gas or combinations of gas that improve surface adhesion. The non-conducting layer 120, may also be coated with another gas-phase non-conducting layer such as ALD derived Al2O3 or any other non-conducting layer that can also improve adhesion between the non-conducting layer 120 and the conducting layer 125.

In one embodiment of the present invention, after the final conducting layer is formed, the entire device may be coated with a passivation non-conducting layer of materials similar to those used to form the initial non-conducting layer. Such a layer can be used to prevent oxidation of the conducting layer 125 and to reduce stress due to thermal mismatch.

In another embodiment of the present invention openings in non-conducting layer 120 are disposed over thermal vias, 101. This allows conducting coatings 125 in FIG. 1 or conducting layers 225 and 226 in FIG. 2 to form thermal connection to thermal vias, 101 or 201 improving thermal transfer from the integrated circuits to heat rejection points thermally connected to the outer conducting layer.

Another embodiment of this invention disposes a second conducting layer, 226, over the second conformal non-conducting layer, 219, as depicted in FIG. 2. This layer may be of a ferrous material providing a high magnetic permeability which in turn increases the effectiveness of isolation due to the diminished skin depth of the material. The decrease conducted current density (and therefore net electric field) as a function of depth in a conductor is given by

E=E_{S}e^{-d/δ} ,(2)

where Es is the electric field at the surface, d is the depth into the conformal conducting layer, and δ is the skin depth of the material. However, smaller skin depths can be achieved by using magnetically permeable materials. As the magnetic permeability, μ, of a conductor increases, its skin depth decreases according to the following relation:

$$δ = \sqrt{\frac{2}{2 π f σ μ}} , \qquad ( 3 )$$

where σ is the material conductivity and f is the frequency. Therefore a magnetic material with a relative permeability of 100, would provide the equivalent shielding as a non-magnetic material with 10 times the thickness. A ferromagnetic material must be used in order to achieve the desired isolation in a light-weight, conformal conducting layer that must be thin. Many such ferromagnetic coatings are available, ranging in relative permeability from 10's to 10,000's. Given the low relative permeability required, those skilled in the art are free to choose the ferromagnetic plating material based upon criteria such as strength, durability, and interfacial adherence. One preferred metal is nickel/cobalt phosphorus which is commonly electroplated. Depending on the particulars of the plating, the material may have a relative magnetic permeability from 100-500 and is extremely durable, as has been previously taught in U.S. Pat. No. 4,673,368. The separation of the two conducting layers by a non-conducting layer can also improves the shielding effectiveness of the coating stack if it is of a material with a large tan δ.

A separate embodiment of the present invention is formed from a plurality of devices as seen in FIG. 3. In this embodiment a plurality of printed circuit boards, 320, are mounted to a backplane, 350, using connectors and mechanical supports, 330, using methods well known to those skilled in the art. In this invention the entire electronic assembly 320, 330, and 350, and all electrical components contained therein are coated with an encapsulating non-conductive coating in a single step. If desired, there may be a masking of connectors on any or all of the PCBs and backplane before deposition of the non-conductive coating. The nonconductive coating may also have openings formed on its surface over advantageously situated ground points. After the formation of openings a conductive encapsulating coating maybe disposed over the entire assembly. Both the non-conductive and conductive coatings use the same gas-phase deposition techniques previously disclosed in this teaching.

As is well known to those skilled in the art, non-conducting layers from gas-phase reactions can be advantageously masked to prevent deposition of the non-conductive layer over connectors situated on PCB 600 as depicted in FIG. 6. Such masks, exemplified by 601 and 602 of FIG. 6, can be formed from liquid polymers with latex bases, waxes, and other forms of sealing polymers as well as sealing mating connectors over those disposed on the article to be coated such as PCB 600. Such masking may be used to prevent deposition of both non-conducting layer 620 and conducting layer 625 over the metal contacts of connectors and other areas that must later be electrically connected. This teaching also discloses a method for the shielding of shrouded connectors as is shown in FIG. 7. In FIG. 7A a shrouded connector 750 is attached to the surface of PCB 700 and masked to prevent the formation of layers 720 and 725 on the sides of the shroud. In FIG. 7B shrouded connector 751 attached to PCB 701 was masked, using methods shown in FIG. 6, to prevent the formation of layers 721 and 726 on the inside of the shroud 751. When the connector half shown in FIG. 7A is mated with that in 7B, layers 726 and 725 are brought into electrical contact providing an effective shield for the connector.

What is claimed is:

1. An electronic device containing a printed circuit board assembly comprised of at least one electronic component and at least two electrical conductors one of which is used to provide power and one of which is used as ground:
a non-conductive layer formed from gas-phase deposition that encapsulates the entire device; and,
a conductive layer formed from gas-phase and/or liquid phase deposition that encapsulates the previously encapsulated device.

2. The device of claim 1, where the non-conducting encapsulant substantially retards the ingress of fluids and gases.

3. The device of claim 1, where the conducting encapsulant substantially retards the ingress of fluids and gases.

4. The device of claim 1 where the thickness of the non-conducting encapsulant is controlled to produce a desired impedance between an electrical conductor in the device and the conducting encapsulant.

5. The device of claim 1, where openings, that do not degrade the encapsulant's resistance to fluid ingress, are formed in the non-conducting encapsulant over at least one metal conductor on the assembly whose electric potential is ground.

6. The device of claim 5, where the openings in the non-conducting encapsulant allow the conducting encapsulant to make electrical contact to the device's electrical ground during deposition.

7. An electronic device containing a printed circuit board assembly comprised of at least one electronic component, at least two electrical conductors one of which is used to provide power and one of which is used as ground, and at least two additional electrical conductors that allow signals or power and ground to be electrically connected to another electrical assembly that is not a part of the device:
a non-conductive layer formed from gas-phase phase deposition that encapsulates the entire device except the contacting surfaces of electrical conductors that allow signals or power and ground to be electrically connected to another electrical assembly that is not a part of the device; and,
a conductive layer formed from gas-phase and/or liquid phase deposition that encapsulates the previously encapsulated device except the contacting surfaces of electrical conductors that allow signals or power and ground to be electrically connected to another electrical assembly that is not a part of the device.

8. The device of claim 7, where the non-conducting encapsulant substantially retards the ingress of fluids and gases.

9. The device of claim 7, where the conducting encapsulant substantially retards the ingress of fluids gases.

10. The device of claim 7 where the thickness of the non-conducting encapsulant is controlled to produce a desired impedance between an electrical conductor in the device and the conducting encapsulant.

11. The device of claim 7, where openings, that do not degrade the encapsulant's resistance to fluid ingress, are formed in the non-conducting encapsulant over at least one metal conductor on the assembly whose electric potential is ground.

12. The device of claim 11, where the openings in the non-conducting encapsulant allow the conducting encapsulant to make electrical contact to the device's electrical ground during deposition.

13. A plurality of electronic devices each containing a printed circuit board assembly comprised of at least one electronic component, and at least two electrical conductors one of which is used to provide power and one of which is used as ground, and at least two additional electrical conductors that allow signals or power and ground to be electrically connected between at least two of the electrical devices within the plurality, and at least two more additional conductors that allow signals or power and ground to be electrically connected to electronic devices outside of the plurality:
a non-conductive layer that encapsulates the entire plurality of devices but not the contacting surfaces of the conductors that connect to electronic devices outside of the plurality that is formed from gas-phase deposition; and,
a conductive layer that encapsulates the entire plurality of devices but not the contacting surface of the conductors that connect to electronic devices outside of the plurality that is formed from gas-phase and/or liquid phase deposition.

14. The device of claim 13, where the non-conducting encapsulant substantially retards the ingress of fluids and gases.

15. The device of claim 13, where the conducting encapsulant substantially retards the ingress of fluids and gases.

16. The device of claim 13 where the thickness of the non-conducting encapsulant is controlled to produce a desired impedance between an electrical conductor in the device and the conducting encapsulant.

17. The device of claim 13, where openings, that do not degrade the encapsulant's resistance to fluid ingress, are formed in the non-conducting encapsulant over at least one metal conductor on the assembly whose electric potential is ground.

18. The device of claim 17, where the openings in the non-conducting encapsulant allow the conducting encapsulant to make electrical contact to the device's electrical ground during deposition.

19. The device of claim 1 wherein a second non-conducting layer is disposed over the conducting layer.

20. The device of claim 19 wherein a second conducting layer is disposed over the second non-conducting layer.

21. The device of claim 20 where the second conducting layer is comprised of a conformal conducting layer with a relative magnetic permeability greater than one.

22. The device of claim 21 that provides a means for a single point of electrical contact between the second conducting layer and system ground.

23. The device of claim 7 wherein a second non-conducting layer is disposed over the conducting layer.

24. The device of claim 23 wherein a second conducting layer is disposed over the second non-conducting layer.

25. The device of claim 24 where the second conducting layer is comprised of a conformal conducting layer with a relative magnetic permeability greater than one.

26. The device of claim 25 that provides a means for a single point of electrical contact between the second conducting layer and system ground.

27. The device of claim 13 wherein a second non-conducting layer is disposed over the conducting layer.

28. The device of claim 27 wherein a second conducting layer is disposed over the second non-conducting layer.

29. The device of claim 28 where the second conducting layer is comprised of a conformal conducting layer with a relative magnetic permeability greater than one.

30. The device of claim 29 that provides a means for a single point of electrical contact between the second conducting layer and system ground.

31. The devices of all claims which contain an electrical connector to pass signals or power between other electronics devices within the device or between other devices, where an electrical connector is masked to protect the electrical contacts of the connectors during deposition of the non-conducting layer.

32. The devices of claim 31 where the masking is also used to protect the electrical contacts of the connectors during deposition of the conducting layer.

33. The devices of claim 32 where the masking is formed to allow the conducting layer to electromagnetically shield the connectors.

34. The devices of all claims referring to openings in the non-conductive layer, where the openings are formed by ablating.

35. The devices of all claims referring to openings in the non-conductive layer, where the openings are formed by chemical etching.

36. The devices of all claims referring to openings in the non-conductive layer, where the openings are formed by mechanical abrasion.

37. The devices of all claims referring to openings in the non-conductive layer, where the openings are formed by etching using accelerated ions.
